(19) United States
(12) Patent Application Publication
(10) Pub. No.: US 2015/0042307 A1
(43) Pub. Date: Feb. 12, 2015

(54) METHOD AND APPARATUS FOR TONE TRACING AND TAGGING USING MOBILE COMPUTER DEVICE

(71) Applicant: SAMEER CHOLAYIL, FORT WORTH, TX (US)

(72) Inventor: SAMEER CHOLAYIL, FORT WORTH, TX (US)

(73) Assignee: TORUSEMD LLC, FORT WORTH, TX (US)

(21) Appl. No.: 13/964,093

(22) Filed: Aug. 11, 2013

(51) Int. Cl. G01R 23/167; G01R 1/067

(52) U.S. Cl. CPC G01R 23/167; G01R 1/06788
USPC 324/66

(57) ABSTRACT

The industry practice to detect and identify objects such as wires, cables, pipes and tuned coils is to inject a known tone from a tone generator into the object by conduction or induction, occasionally with tagging information. The invention is a tone detection apparatus, also known as the tone probe, to detect the presence of such injected tones that makes use of a microphone or audio electrical input of a mobile computer and software application running on the mobile computer such as a contemporary “smart-phone”. The use of a mobile computer reduces the cost of this tone probe and provides the ability to use mobile internet connection to communicate and store the tagging and location information about object under detection. The display of the mobile computer allows providing more information than a typical tone probe.

### CROSS REFERENCE TO RELATED APPLICATIONS

Not Applicable

### FEDERALLY SPONSORED RESEARCH

Not Applicable

### SEQUENCE LISTING OR PROGRAM

Not Applicable

### FIELD OF THE INVENTION

The invention presented here relates to the use of mobile computers such as contemporary smart-phones in tone detection devices used in locating and identifying conductors like wire, pipe or tuned coils, taking advantage of the features available on the mobile computers.

### BACKGROUND OF THE INVENTION

Prior art, U.S. Pat. No. 3,882,287, issued 1975, describes the method of electrically connecting a tone generator to a pair of conductors in a cable bundle. The FIG. 1 of the prior art show detecting of the cable with a non-contact method. FIG. 2 of the prior art show isolating the conductor pair, carrying the tone, within the cable bundle using a probe connected to the conductor and mentally judging the presence and relative amplitude of signal in the conductor under probing through the headphone. These adequately demonstrate the techniques in use in the industry though the size and shape of the equipment has changed.

Prior art U.S. Pat. No. 8,413,901, issued 2013, describes a credit card reader with the audio connections that can be connected to the audio ports of portable computer devices like contemporary ‘smartphone’ to read credit card information coming in as an audio signal.

Many modern tone probes employ a detector probe tip and amplifier stage with filter feeding a audio speaker to enable tone based tracing. There are a few that process signal digitally in the internal microcontroller or DSP IC, and feed a speaker/led to enable tone tracing. AC wiring detector can also be considered a specialized tone probe as the live AC wiring carries 50 or 60 Hz AC signal in most cases without a need for a tone generator to be connected.

### BRIEF SUMMARY OF THE INVENTION

The present invention uses minimal electronic circuits and uses the Mobile Computing device's audio input to do the signal filtering and detection. The mobile computer also allows the present invention to export conductor tagging and closet location information to a server.

One advantage of the present invention is that the mobile computer has a larger screen as well as audio and buzzer to present the information to the user. This allows graphs and charts to be shown. This also allows one or more people to actively coordinate at different locations and make tracing faster. The mobile device like a ‘smartphone’ also allows text and voice communication ability.

The invention keeps the analog circuit simpler and easily re-producible with low variations. The invention is superior to any digital probes available in that the present invention does not need additional circuitry, microprocessors, DSP IC's or battery capacity associated with digital tone probes. The hardware is thus very low cost.

The invention also allows storage of tagging and location information on a server that makes it easy to pull the data for inspections or troubleshooting later on.

A technician usually carries different Tone probe equipment to detect signals from wire tracing, pipe tracing and tuned coil marker tracing. It requires a lot of training to use the User Interfaces of different equipments. The present invention means that there is only one User Interface, with different probes depending on the application, presented on a larger screen of a mobile computer. The small LCD's on present day tone detector probes cannot provide as much information.

### BRIEF DESCRIPTION OF THE SEVERAL VIEWS OF THE DRAWING

FIG. 1 is a pictorial representation of one of the preferred embodiment of the present invention.

FIG. 2A is a pictorial representation of one preferred embodiment of a tone probe tip. FIG. 2B is a pictorial representation of another preferred embodiment of a tone probe tip with longer cable. FIG. 2C is a pictorial representation of one preferred embodiment of a tone probe tip that uses an insulated coil inside it for inductive pick up of the tone signal. FIG. 2D is a pictorial representation of one preferred embodiment of a tone probe tip with exposed metallic conductor for direct connection to wire under probing. FIG. 2E is a pictorial representation of one preferred embodiment of a tone probe tip with the insulated metal piece inside the tone probe tip acting as a capacitive pickup.

FIG. 3A is a block diagram of a preferred embodiment of the invention. FIG. 3B is the pictorial representation of the communication between a server and the mobile computers used in the invention.

### DETAILED DESCRIPTION OF THE INVENTION

The invention described here provides for a less complex, cheaper and a more capable Tone Tracing probe that provides more information.

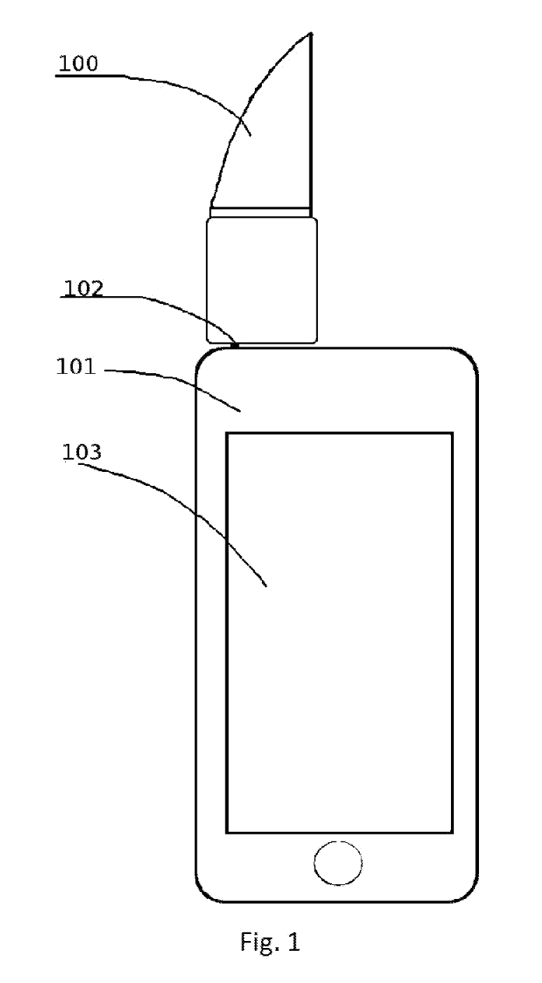

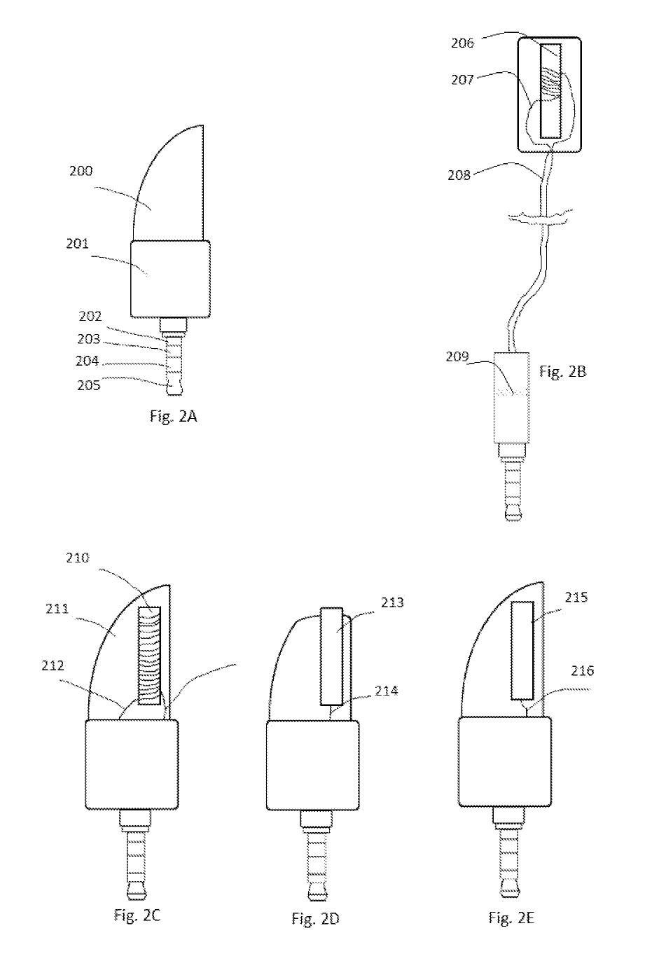

FIG. 1 of Prior art U.S. Pat. No. 3,882,287, issued 1975, shows how a tone is injected into a conductor by electrical conduction for detection by a tone probe. This detection of the tone using a probe tip is shown in FIG. 2. of prior art Pat. No. 3,882,287.

FIG. 1 discloses one embodiment of the invention. The main components of the invention are probe assembly 100 which detects the tone from the conductor under test, audio port 102 used to connect the probe assembly 100 to the mobile computer with software 101 that processes the input audio signal and detects the tone present in the audio input signal. 103 is the large screen display used to display information such as tone frequencies detected and amplitude along with the tagging information. The mobile computer and software application on it 101 allows the operator to save location, cabinet and cable tagging information related to the conductors under test to a server for future reference. The mobile computer with software 101 also allows users to communicate with other users to co-ordinate connecting tone generator to remote end and send the conductor label to the user doing the probing, making cable and conductor tracing and tagging faster.

FIG. 2A discloses the details of an embodiment of the probe tip 100 of FIG. 1. FIG. 2A shows the probe tip casing 200, the enclosure for electronics and battery that may be needed in certain embodiments of the invention 201, common connection of 203, microphone input connection 202, right audio output connection 204 and left audio output connection 205. The signal from the probe tip is fed to the mobile computer 101 microphone port 102 through the microphone input 202 and 203, the ground connection, in this embodiment.

FIG. 2B. discloses the details of an embodiment of the probe tip 100 of FIG. 1. 206 is the core material of the inductor and 207 is the coil used to pick up the signal that is insulated with its case. The cable 208 in this embodiment is long and is separate from the audio port plug 209.

FIG. 2C. discloses the details of an embodiment of the probe tip 100 of FIG. 1. 210 is the core material of the inductor and 212 is the coil used to pick up the signal. The insulating case is 211.

FIG. 2D. discloses the details of an embodiment of the probe tip 100 of FIG. 1. 213 is an insulated metal plate with an exposed metal tip to pick up signal. 214 is the connection to the microphone input pins 202 and common pin 203 of FIG. 2A.

FIG. 2E. discloses the details of an embodiment of the probe tip 100 of FIG. 1. 215 is a completely insulated metal plate to pick up signal. 216 is the connection to the microphone input pins 202 and common pin 203 of FIG. 2A.

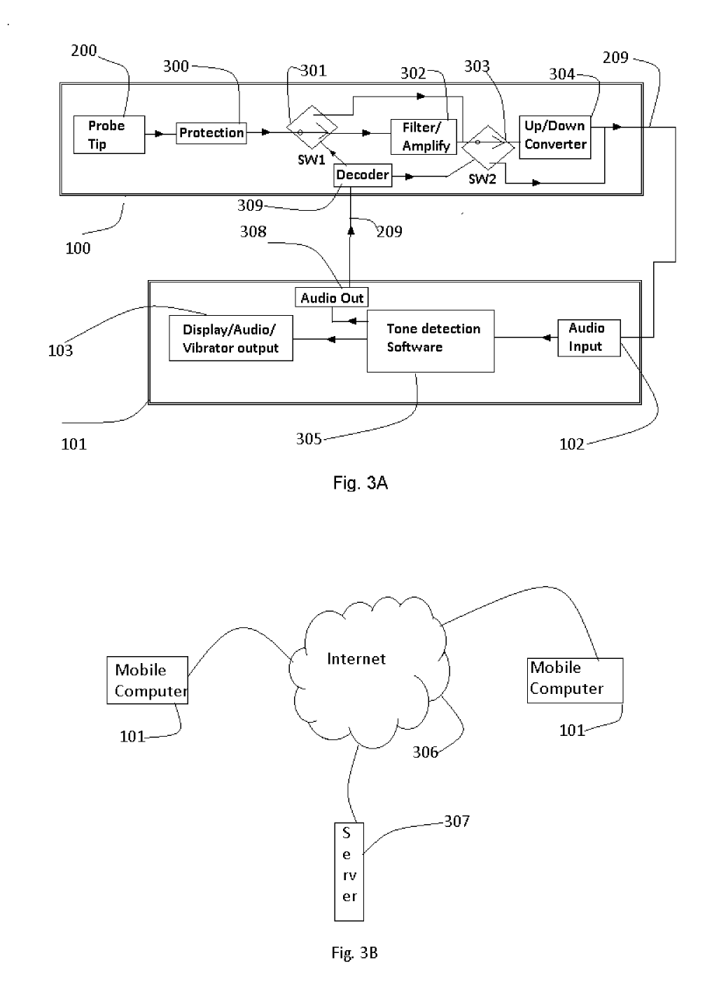

FIG. 3A discloses an embodiment of the invention where the case 201 of FIG. 2A contains electronic circuitry that is powered by a battery or power harvested from an audio output channel. ESD/Over-voltage protection passive device between microphone input and common terminal 300. FIG. 3A also shows the signal path to the mobile computing device 101 through the audio port 102. The items marked 100, 101, 102, 103, 200, 209 have already been described in earlier drawings. 301 is a switch that allows the input signal to bypass filter amplifier circuit 302. 303 is a bypass switch that allows the signal to bypass the up/down converter 304. The bypass switches are controlled by the decoder 309 and signal from one audio out channel 308 of the mobile computer 101. Different tones into the detector 309 allows it to set different settings for the switches 301 and 303. The circuit of FIG. 3A allows amplification or scale down the input signal to present to the audio port 102 of mobile computer 101 before processing the signal. In some cases the input frequency is in subsonic or RF range. In such cases the up/down converter circuit scales down the input frequency range to 40 Hz-20 KHz range for processing by the audio input port 102 of mobile computer 101.2. The software application 305 running on the mobile computer 101 may use different algorithms like goertzel, FFT, narrow band filters, chirp z transform, correlation or statistical signal processing to analyze the tone or tones present in the detected signal. The software application 305 also decodes any tagging information in the input tone based on a particular tag for a particular frequency or demodulating the data contained in the FSK modulation of the input signal that was tagged with FSK data by the tone generator. This tag information if present in the input signal is presented on the display 103.

FIG. 3B discloses the details of an embodiment of the part of the apparatus that allow two users of the apparatus communicate by texting or voice and exchange the tagging and location information of the conductors that they are working on at two ends of a inside or outside cable plant using a pair of the mobile computer 101 and internet connection 306. The server 307 is used to store the tagging and location information for use in the maintenance or troubleshooting of the cable plant. The sever 307 also facilitates the exchange of voice and text information between the software application 305 running on a pair of mobile computer devices 101.

Another embodiment of the invention is capable of working without any electronics in the apparatus except input over-voltage and ESD protection 300. In that case the signal picked up by the probe tip will travel directly to audio port 102 of the mobile computing device 101. The software application running 305 on the device 101 will decode the tones present in the signal and present information on the display 103. A speaker embedded in 201 connected to one of the audio output channels on 102 will be able to put out audio or vibration information for the user.

The invention claimed is:

1. A method and apparatus for the purpose of tone tracing for identifying and tagging electrical wires, cable bundles, tuned coils and metallic pipes, onto which an identification tone has been injected from a tone generator, comprising:
a probe tip, that picks up the tone signal from the object trying to be located and identified by electrical conduction;
a circuit to feed the signal picked up by the said probe tip to an audio input;
a mobile computer device with an audio input connected to the said circuit;
a software application running on the said computer;
that detects the presence of a plurality of tones in the said signal using digital signal processing techniques and presents the results to the user of the said mobile computer device.

2. The probe tip of claim 1 is an electrically insulated conductor for picking up the said tone signal capacitively from probe tip proximity without direct electrical contact.

3. The probe tip of claim 1 is a pickup coil for picking up the said tone signal by electromagnetic induction.

4. The circuit of claim 1 comprises a filter circuit to remove unwanted noise, over-voltage and ESD spikes.

5. The circuit of claim 1 comprises an amplifier circuit to get the signal in optimal amplitude range of the said audio input of the mobile computer.

6. The circuit of claim 1 comprises a frequency up and down converter to get the said input signal within the operating frequency range of the said audio input of the mobile computer.

7. The mobile computer device of claim 1, wherein the device is a computer comprising:
plurality of audio inputs and audio outputs;
display, audio or vibration for user interface.

8. The mobile computer of claim 1 has a microphone input as audio input.

9. The mobile computer of claim 1 has hardware acceleration for digital signal processing calculations.

10. The mobile computer of claim 1 has internet connection.

11. The software application of claim 1 uses FFT algorithm to detect the presence of a tone, or a plurality of tones in the said audio input signal.

12. The software application of claim 1 uses Goertzel algorithm to detect the presence of tone, or a plurality of tones in the said audio input signal one on each pass of the said algorithm.

13. The software application of claim 1 uses Narrow band filter to detect the presence of tone, or a plurality of tones in the said audio input signal one on each pass of the said algorithm

14. The software application of claim 1 uses Chirp Z Transform algorithm to detect the presence of tone, or a plurality of tones in the said audio input signal.

15. The software application of claim 1 uses Statistical signal processing to detect the presence of tone, or a plurality of tones in the said audio input signal.

16. The software application of claim 1 uses Correlation to detect the presence of tone, or a plurality of tones in the said audio input signal one on each pass of the said algorithm.

17. The software application of claim 1 sends tag information and other communication, over the internet to other users of the said application, to help the identification, tagging and review of work locations.

18. The software application of claim 1 decodes the data present in the said audio signal to display tag information sent from a tone generator that includes tag information in the tone output from said tone generator.
